(19) United States
(12) Patent Application Publication
(10) Pub. No.: US 2007/0080371 A1
(43) Pub. Date: Apr. 12, 2007

(54) Display device

(76) Inventors: Seung-Hyun Son, Suwon-si (KR); Gi-Young Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/545,500

(22) Filed: Oct. 11, 2006

(30) Foreign Application Priority Data
Oct. 11, 2005 (KR) 10-2005-0095489

(51) Int. Cl. H01L 29/739

(52) U.S. Cl. 257/194

(57) ABSTRACT

A display device which may include a first substrate and a second substrate facing each other to form a plurality of cells between the first and second substrates, a plurality of first electrodes and a plurality of second electrodes disposed between the first substrate and the second substrate, electron accelerating layers formed on side surfaces of the first electrodes for accelerating and emitting electrons toward the side surfaces when voltages are applied to the first and second electrodes, a gas filled in the cells and excited by the electrons, and a light emitting layer disposed between the first substrate and the second substrate, or on an outer side surface of the first substrate or the second substrate.

### BACKGROUND OF THE INVENTION

1. Field of the Invention

The present invention relates to a display device. More particularly, the present invention relates to a display device configured to operate at a low driving voltage, which may exhibit enhanced luminous efficiency.

2. Description of the Related Art

Plasma display panels (PDPs) may be considered as an alternative to conventional cathode ray tube (CRT) displays. In an exemplary PDP, a discharge gas may be filled between two substrates and a plurality of electrodes may be formed on the two substrates. In an exemplary operation of a PDP, a discharge voltage may be applied to the discharge gas to generate ultraviolet light. The ultraviolet light may excite phosphor layers formed in a predetermined pattern so as to emit visible light and display a desired image.

Generally, PDPs use a discharge gas, for example, Xe. The discharge gas may be ionized and a plasma discharge may occur. The excited Xe may relax to a less energetic state with a concomitant generation of ultraviolet light.

However, in order to display images in a conventional PDP, a significant amount of energy is required to ionize the discharge gas, and, thus, a high driving voltage is needed. However, the luminous efficiency of the plasma display panel is relatively low. In addition, in flat panel lamps adopting the plasma display panel, the discharge gas should be ionized to emit light, and thus, the driving voltage is high and the luminous efficiency is low.

### SUMMARY OF THE INVENTION

The present invention is therefore directed to a display device that substantially overcomes one or more of the problems due to the limitations and disadvantages of the related art.

It is therefore a feature of an exemplary embodiment of the present invention to provide a display device having a structure configured to reduce a driving voltage and increase luminous efficiency.

At least one of the above and other features and advantages of the present invention may be realized by providing a display device which may include a first substrate and a second substrate facing each other to form a plurality of cells between the first and second substrates, a plurality of first electrodes and a plurality of second electrodes disposed between the first substrate and the second substrate, electron accelerating layers formed on side surfaces of the first electrodes for accelerating and emitting electrons toward the side surfaces when voltages are applied to the first and second electrodes, a gas filled in the cells and excited by the electrons, and a light emitting layer disposed between the first substrate and the second substrate, or on an outer side surface of the first substrate or the second substrate.

The electron accelerating layer may include oxidized porous silicon. The electron accelerating layer may include one or more of oxidized porous polysilicon and oxidized porous amorphous silicon.

Each of the electron accelerating layers may include a plurality of tips substantially disposed in a direction parallel to the surface of the electron accelerating layer that is adhered onto the first electrode.

The first and second electrodes may be disposed on the first substrate and the second substrate facing each other, respectively.

The first and second electrodes may be disposed on the first substrate or on the second substrate together with each other.

The electron may have an energy level that is larger than an energy level required to excite the gas in the cell and smaller than an energy level required to ionize the gas.

A plurality of third electrodes may be disposed on side surfaces of the electron accelerating layers. The third electrode may have a mesh structure.

When voltages applied to the first electrode, the second electrode, and the third electrode are V₁, V₂, and V₃, a relation of V₁<V₃≦V₂ may be satisfied.

The first electrodes may be disposed in parallel to the second electrodes. The first electrodes may be disposed to cross the second electrodes.

At least one of the above and other features and advantages of the present invention may also be realized by providing a display device which may include a first substrate and a second substrate facing each other to form a plurality of cells between the first and second substrates, pairs of a plurality of first electrodes and a plurality of second electrodes disposed between the first substrate and the second substrate at the cells, first electron accelerating layers formed on sides of the first electrodes for accelerating and emitting first electrons toward the side surfaces when voltages are applied to the first and second electrodes, second electron accelerating layers formed on sides of the second electrodes for accelerating and emitting second electrons toward the side surfaces when voltages are applied to the first and second electrodes, a gas filled in the cells and excited by the first and second electrons, and a light emitting layer disposed between the first substrate and the second substrate, or on an outer side surface of the first substrate or the second substrate.

The first and second electron accelerating layers may include oxidized porous silicon. The first and second electron accelerating layers may include oxidized porous polysilicon or oxidized porous amorphous silicon.

Each of the first and second electron accelerating layers may include a plurality of tips substantially disposed in a direction parallel to the surface of the electron accelerating layer that is adhered onto the first electrode or the second electrode.

The first and second electrodes may be disposed on the first substrate or on the second substrate together with each other.

The first and second electrons may have an energy level that is larger than an energy level required to excite the gas in the cell and smaller than an energy level required to ionize the gas.

A plurality of third electrodes may be disposed on sides of the first electron accelerating layers, and a plurality of fourth electrodes may be disposed on sides of the second electron accelerating layers. The third and fourth electrodes may have mesh structures.

When voltages applied to the first electrode, the second electrode, the third electrode, and the fourth electrode are V₁, V₂, V₃, and V₄, relations of V₁<V₃ and V₂<V₄ may be satisfied.

The first electrodes may be disposed in parallel to the second electrodes. Address electrodes may be disposed to cross the first electrodes and the second electrodes.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic of a partial, cross-sectional view of a of a display device according to a first exemplary embodiment of the present invention;

FIG. 2 illustrates an expanded view of part A of an electron accelerating layer illustrated in FIG. 1;

FIG. 3 illustrates a graph of energy levels of a Xe discharge gas;

FIGS. 4A through 4D illustrate exemplary voltage waveforms that may be applied to the electrodes of the display device illustrated in FIG. 1;

FIG. 5 illustrates a schematic of a partial, cross-sectional view of a display device according to a second exemplary embodiment of the present invention;

FIG. 6 illustrates a schematic of a partial, cross-sectional view of a display device according to a third exemplary embodiment of the present invention;

FIG. 7 illustrates a schematic of a partial, cross-sectional view of a display device according to a fourth exemplary embodiment of the present invention; and

FIGS. 8A and 8B illustrate exemplary voltage waveforms that may be applied to electrodes of the display device illustrated in FIG. 7.

### DETAILED DESCRIPTION OF THE INVENTION

Korean Patent Application No. 10-2005-0095489 filed on Oct. 11, 2005, in the Korean Intellectual Property Office, and entitled: “Display Device,” is incorporated by reference herein in its entirety.

The present invention will now be described more fully hereinafter with reference to the accompanying drawings, in which exemplary embodiments of the invention are illustrated. The present invention may, however, be embodied in different forms and should not be construed as limited to the exemplary embodiments set forth herein. Rather, these exemplary embodiments are provided so that this disclosure will be thorough and complete, and will fully convey the scope of the present invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers or elements may also be present. Further, it will be understood that when a layer or element is referred to as being “under” another layer or element, it can be directly under, or one or more intervening layers or elements may also be present. In addition, it will also be understood that when a layer or element is referred to as being “between” two layers, two elements, or layer and element, it can be the only layer or element between the two layers, the two elements, or layer and element, or one or more intervening layers or elements may also be present. Like reference numerals refer to like layers or elements throughout.

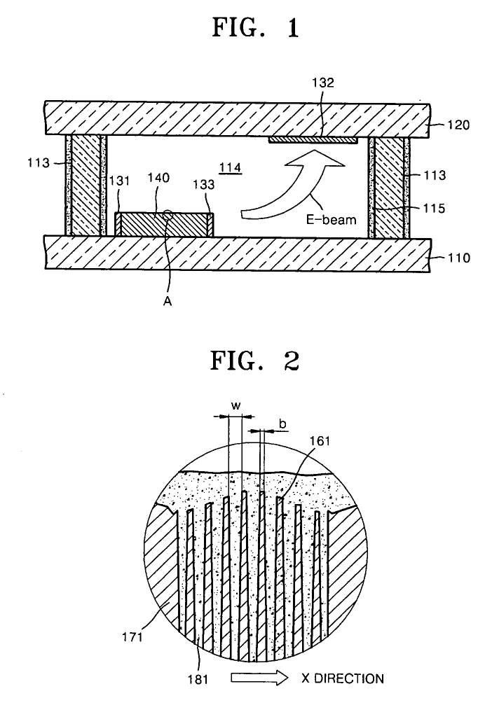

FIG. 1 illustrates a schematic of a partial, cross-sectional view of a display device according to a first exemplary embodiment of the present invention.

Referring to FIG. 1, a first substrate 110 and a second substrate 120 may face each other with a predetermined distance between them. The first substrate 110 and the second substrate 120 may include various materials. For example, the first substrate 110 and the second substrate 120 may include glass having high transmittance properties for visible light. Also, the glass may be colored for improving a bright room contrast. In another implementation, the first substrate 110 and the second substrate 120 may include, for example, a plastic, and may have flexible structures.

A plurality of barrier ribs 113 may be formed between the first substrate 110 and the second substrate 120 to define a space between the first substrate 110 and the second substrate 120 and to form a plurality of cells 114. The plurality of barrier ribs 113 may also prevent electrical and optical cross talk from occurring between the cells 114.

Light emitting layers 115, e.g., red (R), green (G), and blue (B) light emitting layers, may be on the inner walls of the cells 114. The light emitting layer 115 may include a material that generates visible light upon excitation by ultraviolet light. However, the present invention is not limited thereto, and the light emitting layer 115 may generate visible light due to colliding electrons. In another implementation, the light emitting layer 115 may include quantum dots.

A gas, generally Xe, may be filled in the cells 114. However, the gas may be N₂, CO₂, H₂, D₂, CO, Kr, or air. If N₂ is used as the gas, the gas may generate ultraviolet light having a long wavelength, and thus, the light emitting layer 115 may be formed on an outer surface of the first substrate 110 or the second substrate 120. Hereinafter, the gas refers to a gas that is excited by external energy such as accelerated electrons to generate the ultraviolet light. In addition, the gas according to the present invention can be applied as the discharge gas.

A first electrode 131 and a third electrode 133 may be on an upper surface of the first substrate 110 at each of the cells 114, and a second electrode 132 may be on a lower surface of the second substrate 120 at each of the cells 114. The first electrode 131 and the third electrode 133 may extend in parallel to each other. The second electrode 132 may extend in a direction of crossing the first electrode 131 and the third electrode 133. The first and second electrodes 131 and 132 may serve as a cathode and an anode, respectively.

As illustrated in FIG. 1, the first and second electrodes 131 and 132 may be positioned toward left or right sides of an imaginary line (not illustrated) that passes through the center of the cell 114, the imaginary line being perpendicular to the first substrate 110.

The second electrode 132 may include a transparent conductive material, such as an indium tin oxide (ITO), so that visible light may be transmitted through the second electrode 132. In addition, a dielectric layer (not illustrated) may be on the second electrode 132. The second electrode 132 may be formed as a mesh, grid, etc., for example, in order to improve the transmittance of visible light.

An electron accelerating layer 140 may be on a side surface of the first electrode 131 and on a side surface of a third electrode 133. That is, the electron accelerating layer 140 may be between the first and the third electrodes 131, 133. The electron accelerating layer 140 may be adjacent to the second electrode 132. As will be explained in greater detail below regarding FIG. 2, the third electrode may formed as a mesh, grid, etc. The electron accelerating layer 140 may include a material that can accelerate electrons, and may include, for example, oxidized porous silicon. The oxidized porous silicon may include one or more of, for example, oxidized porous polysilicon and oxidized porous amorphous silicon.

FIG. 2 illustrates an expanded view of part A of an electron accelerating layer 140 illustrated in FIG. 1. Referring to FIG. 2, the electron accelerating layer 140 may include, for example, a plurality of polysilicon grains 171, a plurality of tips 161 between the polysilicon grains 171, and SiO₂ layers 181 between the tips 161. A width (b) of an end portion of the tip 161 may be, e.g., about 10 nm to about 20 nm, and an interval (W) between the tips 161 may be about, e.g., 40 nm. The tips 161 may be oriented in a direction substantially parallel to the surface where the electron accelerating layer 140 is on the first electrode 131. That is, the tips 161 may be, for example, perpendicular to the first substrate 110. The tips 161 may be arranged in a direction from the first electrode 131 toward the third electrode 133 (i.e., in an X direction).

The electron accelerating layer 140 having the above structure may be formed in various ways. For example, porous polysilicon may be formed of the polysilicon grains using an anodizing method, and after that, the porous polysilicon may be oxidized using, for example, an electrochemical oxidation method.

The electron accelerating layer 140 may accelerate electrons injected from the first electrode 131, and may emit an electron beam (E-beam) through the third electrode 133 and into the cell 114 when predetermined voltages are applied to the first electrode 131, the third electrode 133, and/or the second electrode 132. The principles for accelerating the electrons in the electron accelerating layer 140 will be discussed in more detail below.

In an exemplary operation, predetermined voltages may be applied to the first electrode 131, the third electrode 133, and/or the second electrode 132, and electrons may be injected from the first electrode 131 to the electron accelerating layer 140 in the X direction (as illustrated in FIG. 2). Since the width of the tip 161 in the electron accelerating layer 140 may be less than a mean free path of the electrons (about 50 nm), the electrons may pass through the tips 161 and may reach an interface between the tips 161 and the SiO₂ layers 181. However, most of the voltage applied to both sides of the electron accelerating layer 140 may be applied to the SiO₂ layers 181, and thus, strong electric fields may be formed on the SiO₂ layers 181. Since the SiO₂ layers 181 may be very thin, the electrons may pass through the SiO₂ layers 181 using a tunneling phenomenon. Whenever the electrons pass through the SiO₂ layers 181, on which strong electric fields may be formed, the electrons may be accelerated. In addition, whenever the electrons move toward the third electrode 133, the acceleration may occur repeatedly. Therefore, the electrons reaching the side surface of the third electrode 133 may have energies that are much higher than that of the electrons in a thermal equilibrium status, that is, energies near the applied voltages.

The electrons may pass through the third electrode 133 and may be emitted into the cell 114. The electrons emitted into the cell 114 may form an electron beam (E-beam—as illustrated in FIG. 1). In order to emit the electrons efficiently, the third electrode 133 may be formed as a mesh, grid, etc.

The electron beam emitted in the cell 114 may excite the gas and the excited gas may generate ultraviolet light. The ultraviolet light may excite the light emitting layers 115 to generate visible light, and the visible light may be emitted toward the second substrate 120. The emitted light may be used as a general lighting source, an image display, etc. According to this exemplary embodiment, since the second electrode 132 is toward a side of the cell 114, the electron beam may be sufficiently attracted across the cell 114.

The electron beam may have an energy level that is higher than that required to excite the gas and an energy level that is smaller than that required to ionize the gas. Therefore, the voltages providing electron energy may be optimized. These optimized voltages may be applied to the first electrode 131, the third electrode 133, and/or the second electrode 132 for exciting the gas using the electron beams.

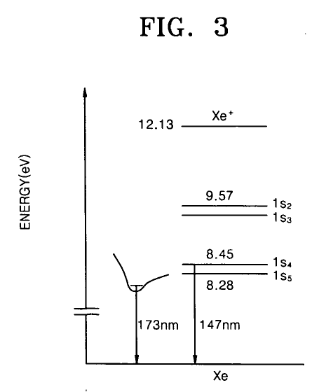

FIG. 3 illustrates a graph of energy levels of a Xe discharge gas. As discussed above, Xe may be a source gas for generating ultraviolet light. Referring to FIG. 3, an energy of about 12.13 eV may be required to ionize the Xe, and an energy of about 8.28 eV or higher may be required to excite the Xe. In more detail, energy levels of about 8.28 eV, 8.45 eV, and 9.57 eV may be required to excite the Xe to states of 1S₅, 1S4, and 1S₂. The excited Xe (Xe*) may generate ultraviolet light having a wavelength of about 147 nm upon relaxation to a lower energetic state. In addition, when excited Xe (Xe*) collides with Xe in the ground state, excimer Xe (Xe₂*) may be generated. When the excimer Xe (Xe₂*) relaxes to a lower energetic state, ultraviolet light having a wavelength of about 173 nm may be generated.

Accordingly, the electron beam emitted into the cell 114 from the electron accelerating layer 140 may have an energy level within a range of about 8.28 eV to about 12.13 eV in order to excite the Xe without ionizing the Xe. For example, the electron beam may have the energy level of about 8.28 eV to about 9.57 eV, about 8.28 eV to about 8.45 eV, about 8.45 eV to about 9.57 eV, etc.

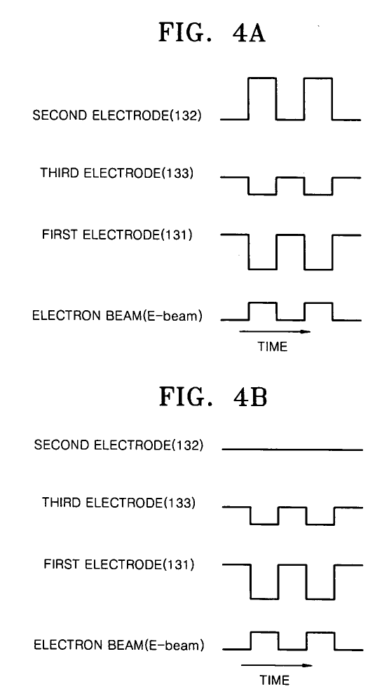

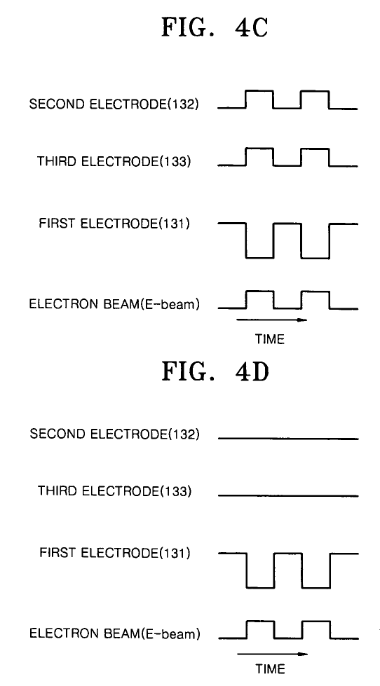

FIGS. 4A through 4D illustrate exemplary voltage waveforms that may be applied to the electrodes of the display device illustrated in FIG. 1.

Referring to FIG. 4A, pulse type voltages may be applied to the first electrode 131, the second electrode 132, and the third electrode 133. For example, the voltages applied to the first electrode 131, the second electrode 132, and the third electrode 133 may be V₁, V₂, and V₃, respectively, and may satisfy a relationship of V₁<V₃<V₂. When the above voltages are applied to the first electrode 131 and the third electrode 133, electrons may be accelerated through the electron accelerating layer 140 and emitted into the cell 114, so the gas may be excited. The emitted electron beam may be accelerated toward the second electrode 132, when the above voltages are applied to the third electrode 133 and the second electrode 132.

By controlling the voltage applied to the second electrode 132, the gas may be induced into a discharging state in a controlled manner. FIG. 4B illustrates other exemplary voltage waveforms that may be applied to the electrodes of the display device illustrated in FIG. 1. As illustrated in FIG. 4B, the second electrode 132 may be grounded. In this case, the electrons reaching the second electrode 132 may be emitted to the outside.

Referring to FIG. 4C, voltages applied to the first electrode 131, the second electrode 132, and the third electrode 133 may satisfy a relationship of V₁<V₃=V₂. When the above voltages are applied to the first electrode 131 and the third electrode 133, the electrons may be accelerated through the electron accelerating layer 140 and emitted into the cell 114, and the gas may be excited by the electron beam.

FIG. 4D illustrates other exemplary voltage waveforms that may be applied to the electrodes of the display device in FIG. 1. As illustrated in FIG. 4D, the second electrode 132 and the third electrode 133 may be grounded. The electrons reaching the second electrode 132 may be emitted to the outside.

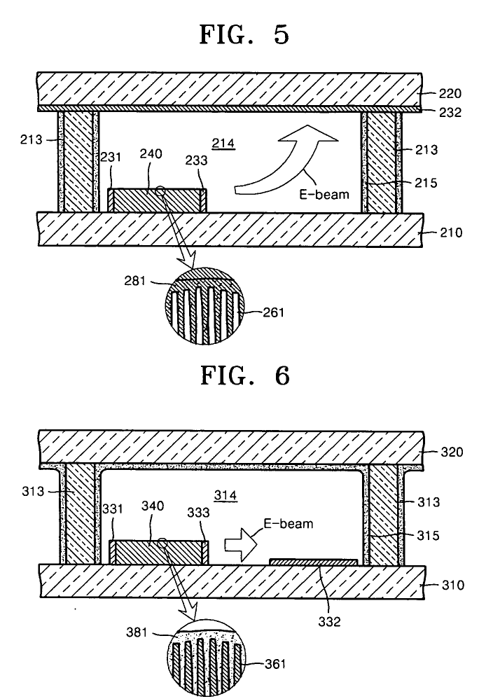

FIG. 5 illustrates a schematic of a partial, cross-sectional view of a display device according to a second exemplary embodiment of the present invention.

Referring to FIG. 5, a first substrate 210 and a second substrate 220 may face each other with a predetermined distance between them. The first substrate 210 and the second substrate 220 may include, for example, a glass or a plastic material. Barrier ribs 213 may be formed between the first substrate 210 and the second substrate 220 to define a space between the first substrate 210 and the second substrate 220 and to form the cells 214. A light emitting layer 215 may be on the inner walls of the cell 214, and a gas, such as Xe, may be filled in the cell 214.

On an upper surface of the first substrate 210, a first electrode 231 may be formed at each of the cells 214, and on a lower surface of the second substrate 220, a second electrode 232 may be formed at each of the cells 214 in a direction of crossing the first electrode 231.

The first electrode 231 and the second electrode 232 may be a cathode and an anode, respectively. The second electrode 232 may include a transparent conductive material, such as ITO. The second electrode 232 may be formed as a mesh, grid, etc., for example, in order to improve the transmittance of visible light.

An electron accelerating layer 240 may be on a side surface of the first electrode 231 and a side surface of the third electrode 233. That is, the electron accelerating layer 240 may be between the first and the third electrodes 231, 233. The third electrode 233 may be formed as a mesh, grid, etc. The electron accelerating layer 240 may include a material that can accelerate the electrons, and may include, for example, oxidized porous silicon. The oxidized porous silicon may include one or more of, for example, oxidized porous polysilicon and oxidized porous amorphous silicon.

The electron accelerating layer 240 may include a plurality of tips 261. The tips 261 may be substantially parallel to a surface where the electron accelerating layer 240 may be on the first electrode 231. That is, the tips 261 may be, for example, perpendicular to the first substrate 210. The tips 261 may be arranged in parallel to each other along a direction from the first electrode 231 to the third electrode 233. SiO₂ layers 281 may be between the tips 261.

The structure and the electron accelerating properties of the electron accelerating layer 240 according to the second exemplary embodiment may be similar to those of the first exemplary embodiment. Accordingly, a detailed description thereof will not be repeated.

In an exemplary operation, predetermined voltages may be applied to the first electrode 231, the third electrode 233, and/or the second electrode 232, and electrons may be injected from the first electrode 231 to the electron accelerating layer 240 in the X direction (as illustrated in FIG. 2). The electron accelerating layer 240 may accelerate the electrons and may emit an electron beam through the third electrode 233 and into the cell 214. The third electrode 233 may be formed as a mesh, grid, etc., so that the electrons accelerated by the electron accelerating layer 240 may be sufficiently emitted into the cell 214.

The electron beam emitted into the cell 214 may excite the gas, and the excited gas may generate ultraviolet light. The ultraviolet light may excite the light emitting layer 215 to generate visible light, and the visible light may be emitted toward the second substrate 220.

The electron beam may have an energy level that is higher than that required to excite the gas and an energy level that is smaller than that required to ionize the gas. The electron beam may have an energy level within a range of about 8.28 eV to about 12.13 eV in order to excite Xe without ionizing the Xe. For example, the electron beam may have the energy level of about 8.28 eV to about 9.57 eV, about 8.28 eV to about 8.45 eV, about 8.45 eV to about 9.57 eV, etc.

The voltage waveforms illustrated in FIGS. 4A through 4D may be applied to the electrodes of the display device having the above structure.

FIG. 6 illustrates a schematic of a partial, cross-sectional view of a display device according to a third exemplary embodiment of the present invention.

Referring to FIG. 6, a first substrate 310 and a second substrate 320 may face each other with a predetermined distance between them. The first substrate 310 and the second substrate 320 may include, for example, a glass or a plastic material. Barrier ribs 313 may be formed between the first substrate 310 and the second substrate 320 to define a space between the first substrate 310 and the second substrate 320 and to form cells 314. A light emitting layer 315 may be on the inner walls of the cell 314, and a gas, such as Xe, may be filled in the cell 314.

A first electrode 331 and a third electrode 333 may be on an upper surface of the first substrate 310 at each of the cells 314. The first electrode 331 and the third electrode 333 may extend parallel to each other. The second electrode 332 may also be on the upper surface of the first substrate 310. The second electrode may extend in a direction of crossing the first electrode 331 and the third electrode 333. The first electrode 331 and the second electrode 332 may be a cathode and an anode, respectively.

An electron accelerating layer 340 may be on a side surface of the first electrode 331 and a side surface of the third electrode 333. That is, the electron accelerating layer 340 may be between the first and the third electrodes 331, 333. The third electrode 333 may be formed as a mesh, grid, etc. The electron accelerating layer 340 may include a material that that can accelerate the electrons, and may include, for example, oxidized porous silicon. The oxidized porous silicon may include one or more of, for example, oxidized porous polysilicon and oxidized porous amorphous silicon.

The electron accelerating layer 340 may include a plurality of tips 361. The tips 361 may be substantially parallel to a surface where the electron accelerating layer 340 may be on the first electrode 313. That is, the tips 361 may be, for example, perpendicular to the first substrate 310. The tips 361 may be arranged in parallel to each other along a direction from the first electrode 331 to the third electrode 333. SiO₂ layers 381 may be between the tips 361.

The structure and the electron accelerating properties of the electron accelerating layer 340 according to the third exemplary embodiment may be similar to those of the previous exemplary embodiments. Accordingly, a detailed description thereof will not be repeated.

In an exemplary operation, predetermined voltages may be applied to the first electrode 331, the third electrode 333, and/or the second electrode 332, and electrons may be injected from the first electrode 331 to the electron accelerating layer 340 (as illustrated in FIG. 2). The electron accelerating layer 340 may accelerate the electrons and may emit an electron beam through the third electrode 333 and into the cell 314. The third electrode 333 may be formed as a mesh, grid, etc., so that the electrons accelerated by the electron accelerating layer 340 may be sufficiently emitted into the cell 314.

The electron beam emitted into the cell 314 may excite the gas, and the excited gas may generate ultraviolet light. The ultraviolet light may excite the light emitting layer 315 to generate the visible light, and the visible light may be emitted toward the second substrate 320.

The electron beam may have an energy level that is higher than that required to excite the gas and an energy level that is smaller than that required to ionize the gas. The electron beam may have an energy level within a range of about 8.28 eV to about 12.13 eV in order to excite Xe without ionizing the Xe. For example, the electron beam may have the energy level of about 8.28 eV to about 9.57 eV, about 8.28 eV to about 8.45 eV, about 8.45 eV to about 9.57 eV, etc.

The voltage waveforms illustrated in FIGS. 4A through 4D may be applied to the electrodes of the display device having the above structure.

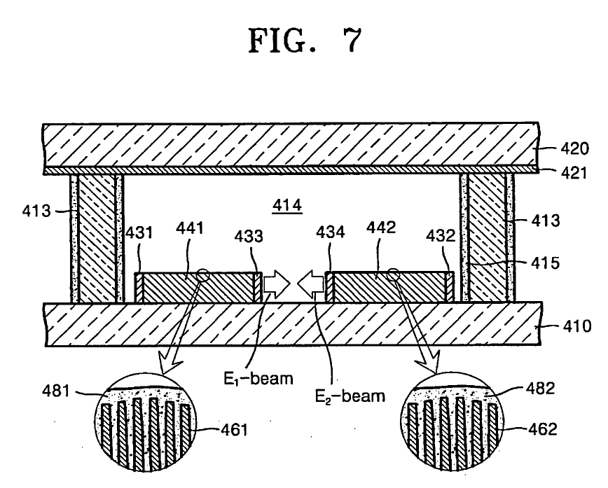

FIG. 7 illustrates a schematic of a partial, cross-sectional view of a display device according to a fourth exemplary embodiment of the present invention.

Referring to FIG. 7, a first substrate 410 and a second substrate 420 may face each other with a predetermined distance between them. The first substrate 410 and the second substrate 420 may include, for example, a glass or a plastic material. Barrier ribs 413 may be formed between the first substrate 410 and the second substrate 420 to define a space between the first substrate 410 and the second substrate 420 and to form cells 414. A light emitting layer 415 may be on the inner walls of the cell 414, and a gas, such as Xe, may be filled in the cell 414.

A pair of a first electrode 431 and a second electrode 432 may be formed at each of the cells 414 on the first substrate 410. The first and second electrodes 431 and 432 may extend in parallel to each other. Address electrodes 421 crossing the first and second electrodes 431 and 432 may be disposed on the second substrate 420.

A first electron accelerating layer 441 may be formed on a side of the first electrode 431, which faces the second electrode 432, and a third electrode 433, which may be a grid electrode 433, may be formed on a side of the first electron accelerating layer 441. A second electron accelerating layer 442 may be formed on a side of the second electrode 431, which faces the first electrode 431, and a fourth electrode 434, which may be a grid electrode, may be formed on a side of the second electron accelerating layer 442.

The first and second electron accelerating layers 441 and 442 may include a material that can accelerate the electrons, and may include, for example, oxidized porous silicon. The oxidized porous silicon may include one or more of, for example, oxidized porous polysilicon and oxidized porous amorphous silicon.

The first electron accelerating layer 441 may include a plurality of tips 461. The tips 461 may be oriented in a direction substantially parallel to the surface where the first electron accelerating layer 441 is on the first electrode 431. That is, the tips 461 may be, for example, perpendicular to the first substrate 410. The tips 461 may be arranged in parallel to each other along a direction from the first electrode 431 to the third electrode 433. SiO₂ layers 481 may be between the tips 461. In addition, the second electron accelerating layer 442 may include a plurality of tips 462. The tips 462 may be oriented in a direction substantially parallel to the surface where the second electron accelerating layer 442 is on the first electrode 434. That is, the tips 462 may also be, for example, perpendicular to the first substrate 410. The tips 462 may be arranged in parallel to each other along a direction from the first electrode 434 to the third electrode 435. SiO₂ layers 482 may be between the tips 462.

The structure and the electron accelerating properties of the first and second electron accelerating layers 441 and 442 according to the fourth exemplary embodiment may be similar to those of the previous exemplary embodiments. Accordingly, a detailed description thereof will not be repeated.

In an exemplary operation, predetermined voltages may be applied to the first electrode 431, the third electrode 433, and/or the second electrode 432, and electrons may be injected from the first electrode 431 to the first electron accelerating layer 441 (as illustrated in FIG. 2). The first electron accelerating layer 441 may accelerate the electrons and may emit a first electron beam (E₁-beam) into the cell 414. In addition, predetermined voltages may be applied to the second electrode 432, the fourth electrode 434, and/or the first electrode 431, and the second electron accelerating layer 442 may emit a second electron beam (E₂-beam) into the cell 414.

The first and second electron beams (E₁-beam and E₂-beam) may be alternately emitted into the cell 414 since an AC voltage may be applied between the first and second electrodes 431 and 432. Each of the first and second electron beams may excite the gas, and the excited gas may generate ultraviolet light. The ultraviolet light may excite the light emitting layer 415 while stabilizing. Further, the first and second electron beams (E₁-beam and E₂-beam) may have an energy level that is higher than that required to excite the gas and an energy level that is smaller than that required to ionize the gas. The electron beams may have an energy level within a range of about 8.28 eV to about 12.13 eV in order to excite the Xe.

The third and fourth electrodes 433 and 434 may be formed as meshes so that the electrons accelerated by the first and second electron accelerating layers 441 and 442 may be emitted into the cell 414 sufficiently.

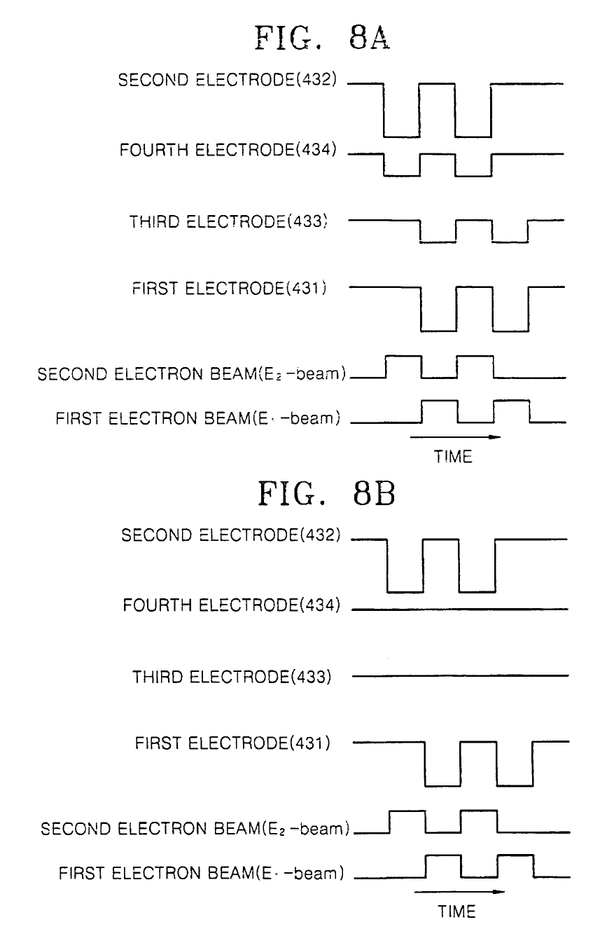

FIGS. 8A and 8B illustrate exemplary voltage waveforms that may be applied to the electrodes of the display device illustrated in FIG. 7. Referring to FIG. 8A, pulse type voltages may be applied to the first, second, third, and fourth electrodes 431, 432, 433, and 434.

Referring to FIG. 8A, the voltages applied to the first, second, third, and fourth electrodes 431, 432, 433, and 434 may be V₁, V₂, V₃, and V₄, and may satisfy a relationship of V₁<V₃ and V₂<V₄. When the above voltages are applied to the electrodes, the first electron beam (E₁-beam) may be emitted into the cell 414 by the voltages applied to the first electrode 431, the third electrode 433, and/or the second electrode 432 through the first electron accelerating layer 441, and the second electron beam (E₂-beam) may be emitted into the cell 414 through the second electron accelerating layer 442 by the voltages applied to the second electrode 432, the fourth electrode 434, and/or the first electrode 431.

By applying an AC voltage to the first electrode 431 and the second electrode 432, the first and second electron beams (E₁-beam and E₂-beam) may be alternately emitted into the cell 414 to excite the gas in the cell 414. The third electrode 433 and the fourth electrode 434 may be grounded as illustrated in FIG. 8B.

According to the display device of the present invention, the energy level of the electron beam does not need to be high enough to ionize the excited gas in order to generate visible light. Therefore, the driving voltage of the device may be lowered and the brightness of the display device may be improved, and thus, the luminous efficiency may be improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A display device, comprising:
a first substrate and a second substrate facing each other to form a plurality of cells between the first and second substrates;
a plurality of first electrodes and a plurality of second electrodes disposed between the first substrate and the second substrate;
electron accelerating layers formed on side surfaces of the first electrodes for accelerating and emitting electrons toward the side surfaces when voltages are applied to the first and second electrodes;
a gas filled in the cells and excited by the electrons; and
a light emitting layer disposed between the first substrate and the second substrate, or on an outer side surface of the first substrate or the second substrate.

2. The display device as claimed in claim 1, wherein the electron accelerating layer includes oxidized porous silicon.

3. The display device as claimed in claim 2, wherein the electron accelerating layer includes oxidized porous polysilicon or oxidized porous amorphous silicon.

4. The display device as claimed in claim 2, wherein each of the electron accelerating layers includes a plurality of tips substantially disposed in a direction parallel to the surface of the electron accelerating layer that is adhered onto the first electrode.

5. The display device as claimed in claim 1, wherein the first and second electrodes are disposed on the first substrate and the second substrate facing each other, respectively.

6. The display device as claimed in claim 1, wherein the first and second electrodes are disposed on the first substrate or on the second substrate together with each other.

7. The display device as claimed in claim 1, wherein the electron has an energy level that is larger than an energy level required to excite the gas in the cell and smaller than an energy level required to ionize the gas.

8. The display device as claimed in claim 1, further comprising:
a plurality of third electrodes disposed on side surfaces of the electron accelerating layers.

9. The display device as claimed in claim 8, wherein the third electrode has a mesh structure.

10. The display device as claimed in claim 8, wherein when the voltages applied to the first electrode, the second electrode, and the third electrode are V₁, V₂, and V₃, a relation of V₁<V₃≦V₂ is satisfied.

11. The display device as claimed in claim 1, wherein the first electrodes are disposed in parallel to the second electrodes.

12. The display device as claimed in claim 1, wherein the first electrodes are disposed to cross the second electrodes.

13. A display device, comprising:
a first substrate and a second substrate facing each other to form a plurality of cells between the first and second substrates;
pairs of a plurality of first electrodes and a plurality of second electrodes disposed between the first substrate and the second substrate at the cells;
first electron accelerating layers formed on sides of the first electrodes for accelerating and emitting first electrons toward the side surfaces when voltages are applied to the first and second electrodes;
second electron accelerating layers formed on sides of the second electrodes for accelerating and emitting second electrons toward the side surfaces when voltages are applied to the first and second electrodes;
a gas filled in the cells and excited by the first and second electrons; and
a light emitting layer disposed between the first substrate and the second substrate, or on an outer side surface of the first substrate or the second substrate.

14. The display device as claimed in claim 13, wherein the first and second electron accelerating layers include oxidized porous silicon.

15. The display device as claimed in claim 14, wherein the first and second electron accelerating layers include oxidized porous polysilicon or oxidized porous amorphous silicon.

16. The display device as claimed in claim 14, wherein each of the first and second electron accelerating layers includes a plurality of tips substantially disposed in a direction parallel to the surface of the electron accelerating layer that is adhered onto the first electrode or the second electrode.

17. The display device as claimed in claim 13, wherein the first and second electrodes are disposed on the first substrate or on the second substrate together with each other.

18. The display device as claimed in claim 13, wherein the first and second electrons have an energy level that is larger than an energy level required to excite the gas in the cell and smaller than an energy level required to ionize the gas.

19. The display device as claimed in claim 13, further comprising:
a plurality of third electrodes disposed on sides of the first electron accelerating layers; and
a plurality of fourth electrodes disposed on sides of the second electron accelerating layers.

20. The display device as claimed in claim 19, wherein the third and fourth electrodes have mesh structures.

21. The display device as claimed in claim 19, wherein when the voltages applied to the first electrode, the second electrode, the third electrode, and the fourth electrode are V₁, V₂, V₃, and V₄, relations of V₁<V₃ and V₂<V₄ are satisfied.

22. The display device as claimed in claim 13, wherein the first electrodes are disposed in parallel to the second electrodes.

23. The display device as claimed in claim 22, further comprising:
address electrodes disposed to cross the first electrodes and the second electrodes.
